(19) United States
(12) Patent Application Publication
(10) Pub. No.: US 2026/0171966 A1
(43) Pub. Date: Jun. 18, 2026

(54) SIGNAL GENERATION DEVICE AND FREQUENCY CALIBRATION CIRCUIT

(71) Applicant: RichWave Technology Corp., Taipei (TW)

(72) Inventor: Po Chun Chang, Taipei (TW)

(73) Assignee: RichWave Technology Corp., Taipei (TW)

(21) Appl. No.: 19/007,557

(22) Filed: Jan. 2, 2025

(30) Foreign Application Priority Data
Dec. 12, 2024 (TW) 113148520

(51) Int. Cl. H03B 5/12

(52) U.S. Cl. CPC H03B 5/1212; H03B 2200/004

(57) ABSTRACT

A signal generation device and a frequency calibration circuit are provided. The signal generation device includes a voltage controlled oscillator (VCO) and the frequency calibration circuit. The VCO provides an oscillation signal according to a first control signal and a second control signal. The frequency calibration circuit compares the first control signal to at least one threshold voltage to generate at least one comparison signal, and generates the second control signal according to the at least one comparison signal. A shift direction of a voltage level of the at least one threshold is the same as a shift direction of a voltage level of a direct current (DC) component of the oscillation signal.

### CROSS-REFERENCE TO RELATED APPLICATION

This application claims the priority benefit of Taiwan application serial no. 113148520, filed on Dec. 12, 2024. The entirety of the above-mentioned patent application is hereby incorporated by reference herein and made a part of this specification.

### BACKGROUND

### Technical Field

The disclosure relates to a signal generation device and a frequency calibration circuit, and in particular relates to a signal generation device and a frequency calibration circuit that may dynamically adjust the frequency of the oscillation signal from a voltage controlled oscillator.

### Description of Related Art

In a signal generation device, a phase locked loop may include a voltage controlled oscillator that provides an output signal. A frequency calibration circuit may be disposed to calibrate the frequency of the output signal generated by the phase locked loop. For example, at least one threshold voltage may be predetermined according to the optimal linear range of the voltage controlled oscillator, and the frequency of the output signal may be determined and adjusted by the frequency calibration circuit based on the threshold voltage. Generally speaking, the threshold voltage may have a fixed level. In practice, the optimal linear range of the voltage controlled oscillator may shift due to the change of the operating voltage, current, and temperature. In such a case, a threshold voltage with a fixed level may be not so advantageous for an accurate frequency calibration.

### SUMMARY

A signal generation device and a frequency calibration circuit are provided in the disclosure, and they may be configured to determine and adjust the oscillation frequency of an signal based on a dynamically changing threshold voltage.

A signal generation device is provided in an embodiment of the disclosure. The signal generation device includes a voltage controlled oscillator and a frequency calibration circuit. The voltage controlled oscillator provides an oscillation signal according to a first control signal and a second control signal. The frequency calibration circuit is coupled to the voltage controlled oscillator. The frequency calibration circuit compares the first control signal to at least one threshold voltage to generate at least one comparison signal, and further generates the second control signal according to the at least one comparison signal. A shift direction of a voltage level of the at least one threshold voltage is the same as a shift direction of a voltage level of a direct current (DC) component of the oscillation signal.

A frequency calibration circuit is provided in another embodiment of the disclosure. The frequency calibration circuit is coupled to a voltage controlled oscillator. The voltage controlled oscillator provides an oscillation signal according to a first control signal and a second control signal. The frequency calibration circuit compares the first control signal to at least one threshold voltage to generate at least one comparison signal, and further generates the second control signal according to the at least one comparison signal. A shift direction of a voltage level of the at least one threshold voltage is the same as a shift direction of a voltage level of a direct current (DC) component of the oscillation signal.

### BRIEF DESCRIPTION OF THE DRAWINGS

FIG. 1 is a schematic diagram of a signal generation device according to an embodiment of the disclosure.

FIG. 2 is a schematic diagram of a signal generation device according to another embodiment of the disclosure.

FIG. 3A to FIG. 3B are schematic diagrams of a voltage controlled oscillator and a capacitor array thereof according to at least one embodiment of the disclosure.

FIG. 4A to FIG. 4D are schematic diagrams of various reference voltage generators according to at least one embodiment of the disclosure.

FIG. 5 is a schematic diagram of a voltage buffer of a signal generation device according to an embodiment of the disclosure.

### DETAILED DESCRIPTION OF DISCLOSED EMBODIMENTS

The disclosure may be understood by referring to the following detailed description in conjunction with the accompanying drawings. It should be noted that, for the sake of simplicity, the drawings may only depict some elements/steps and may not be drawn to scale. In the accompanying drawings, the drawings illustrate the general features of the elements, methods, structures, and/or materials used in the particular embodiments. In addition, the number and size of each of the features in the figures are for illustration purposes only, and are not intended to limit the scope of the disclosure. For example, the relative sizes, thicknesses, and locations of each of the elements, regions, and/or structures may be reduced or enlarged for clarity. Terms used to indicate directions in the disclosure, such as “inside,” “outside,” “up,” “down,” “front,” “back,” “left,” and “right,” are for the purpose of describing relative positions and are not used to limit the disclosure.

Those skilled in the art will understand that within the industry, the same element/step may be referred to by different names or reference numerals. The disclosure does not intend to distinguish between elements/steps that have the same function but have different names. Herein, when it is mentioned that an element is selectively disposed or optionally disposed, it means that the element may be disposed or not disposed according to requirements, which all fall within the scope of the embodiments.

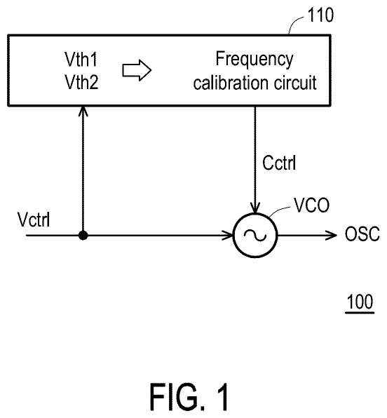

Referring to FIG. 1, FIG. 1 is a schematic diagram of a signal generation device 100 according to an embodiment of the disclosure. The signal generation device 100 may include a voltage controlled oscillator VCO and a frequency calibration circuit 110.

In some embodiments, the voltage controlled oscillator VCO may provide an oscillation signal OSC according to at least one control signal. The at least one control signal may include, for example, a first control signal Vctrl and a second control signal Cctrl. Further, the first control signal Vctrl may be an analog control signal, and the second control signal Cctrl may be a digital control signal. The control signals Vctrl and Cctrl may be configured to change the frequency and/or phase of the oscillation signal OSC.

In some embodiments, the frequency calibration circuit 110 may be coupled to the voltage controlled oscillator VCO to calibrate the frequency of the oscillation signal generated by the voltage controlled oscillator VCO. The frequency calibration circuit 110 may receive the first control signal Vctrl and generate the second control signal Cctrl based on the first control signal Vctrl. In detail, the frequency calibration circuit 110 compares the first control signal Vctrl to at least one threshold voltage (e.g., the first threshold voltage Vth1, the second threshold voltage Vth2), thereby generating one or more comparison signals. The frequency calibration circuit 110 then generates the second control signal Cctrl according to the obtained comparison signal. In this embodiment, the threshold voltages Vth1 and Vth2 may be generated internally in the frequency calibration circuit 110.

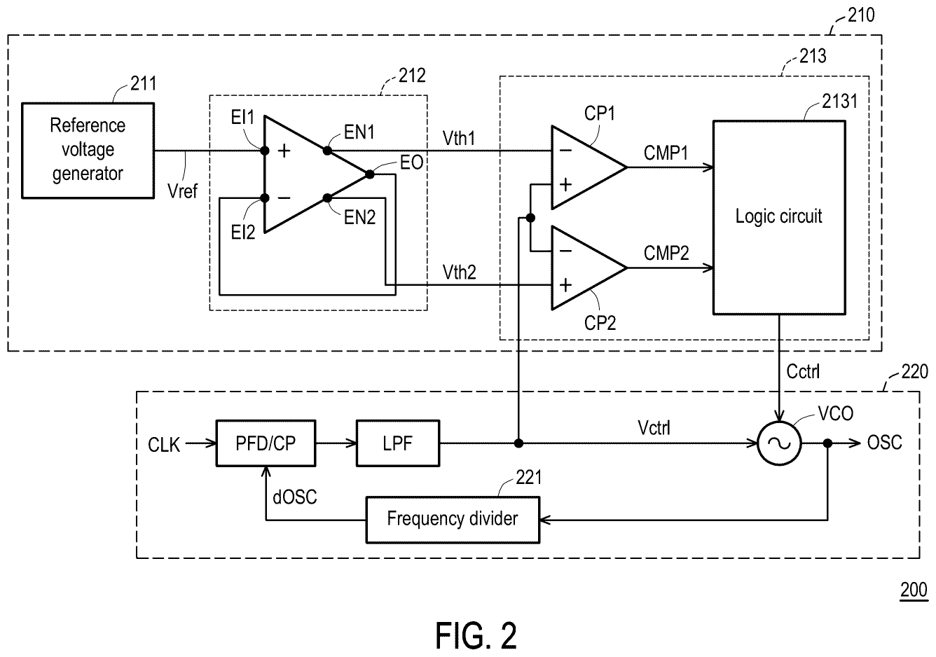

Referring to FIG. 2, FIG. 2 is a schematic diagram of a signal generation device 200 according to another embodiment of the disclosure. The signal generation device 200 includes a phase locked loop 220 and a frequency calibration circuit 210.

As shown in FIG. 2, the phase locked loop 220 may include a voltage controlled oscillator VCO. The phase locked loop 220 may also include a phase frequency detector PFD and/or a charge pump circuit CP, a loop filter LPF, and a frequency divider 221. The phase frequency detector PFD and/or the charge pump circuit CP may receive a clock signal CLK and a frequency-divided signal dOSC. The phase frequency detector PFD detects the phase difference and/or frequency difference between the clock signal CLK and the frequency-divided signal dOSC. The charge pump circuit CP generates a charging or discharging current according to the phase difference and/or frequency difference, and the charging or discharging current flow to the loop filter LPF. In addition, the frequency divider 221 is coupled between the voltage controlled oscillator VCO and the phase frequency detector PFD and/or the charge pump circuit CP, and is configured to divide the oscillation signal OSC to generate the frequency-divided signal dOSC. It is worth noting that the phase frequency detector PFD and/or the charge pump circuit CP, the loop filter LPF, and the frequency divider 221 in the embodiment may each be well known to those of ordinary skill in the art, and are not particularly limited.

In some embodiments, the frequency calibration circuit 210 may include a reference voltage generator 211, a voltage buffer 212, and a comparison logic circuit 213. The reference voltage generator 211 may be configured to generate a reference voltage Vref. The voltage buffer 212 may be coupled to the output terminal of the reference voltage generator 211, so as to receive the reference voltage Vref and generate at least one threshold voltage, such as threshold voltages Vth1 and/or Vth2, according to the reference voltage Vref. The comparison logic circuit 213 may be coupled to the output terminal of the voltage buffer 212 to receive the threshold voltages Vth1 and/or Vth2. Further details may be described below.

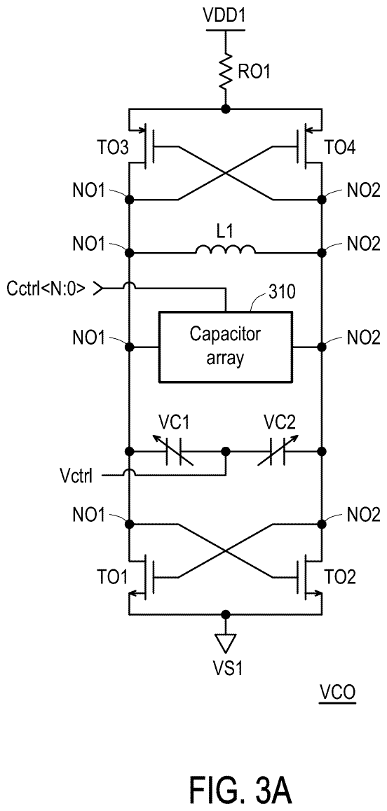

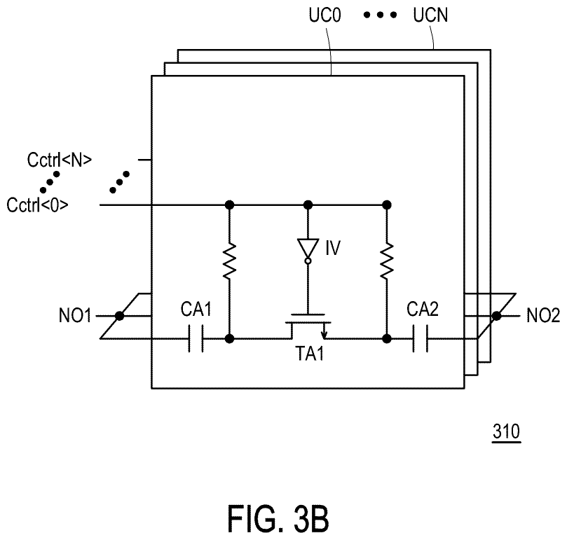

Referring to FIG. 3A and FIG. 3B, FIG. 3A illustrates an exemplary voltage controlled oscillator VCO, and FIG. 3B illustrates an exemplary capacitor array 310 of a voltage controlled oscillator. As shown in FIG. 3A, the voltage controlled oscillator VCO may include transistors TO1 to TO4 and a resistor RO1. For the sake of clarity, the transistors TO1 to TO4 of the voltage controlled oscillator VCO may be respectively referred to as the first to fourth transistors TO1 to TO4.

In detail, in the voltage controlled oscillator VCO, as for the first transistor TO1, the first terminal may be coupled to the voltage terminal VS1, the second terminal may be coupled to the first node NO1, and the control terminal may be coupled to the second node NO2. As for the second transistor TO2, the first terminal may be coupled to the voltage terminal VS1, the second terminal may be coupled to the second node NO2, and the control terminal may be coupled to the first node NO1. As for the third transistor TO3, the first terminal may be coupled to the first node NO1, the second terminal may be coupled to the voltage terminal VDD1 via the resistor RO1, and the control terminal may be coupled to the second node NO2. As for the fourth transistor TO4, the first terminal may be coupled to the second node NO2, the second terminal may be coupled to the voltage terminal VDD1 via the resistor RO1, and the control terminal may be coupled to the first node NO1. In the above embodiment, the resistor RO1 is coupled between the voltage terminal VDD1 and the third transistor TO3, and is coupled between the voltage terminal VDD1 and the fourth transistor TO4.

In the above embodiment, the transistors TO1 and TO2 may form a cross-coupled transistor pair, and the transistors TO3 and TO4 may form another cross-coupled transistor pair. The voltage controlled oscillator VCO may provide the oscillation signal OSC at one of the nodes NO1 and NO2.

Herein, when referring to a transistor, it may include, for example, a P-type transistor and an N-type transistor. For example, for a field effect transistor (FET), the first terminal of the transistor may, for example, correspond to one of the drain and the source, the second terminal may correspond to the other one of the drain and the source, and the control terminal may correspond to the gate. For a bipolar transistor (BJT), the first terminal of the transistor may, for example, correspond to one of the collector and the emitter, the second terminal may correspond to the other one of the collector and the emitter, and the control terminal may correspond to the base. For example, as shown in FIG. 3A, the transistors TO1 and TO2 may be N-type transistors, and the first terminal and the second terminal thereof may, for example, respectively correspond to the source and the drain. The transistors TO3 and TO4 may be P-type transistors, and the first terminal and second terminal thereof may, for example, respectively correspond to the drain and the source.

As shown in FIG. 3A, the voltage controlled oscillator VCO may also include at least one variable capacitor (e.g., variable capacitors VC1 and VC2) and a capacitor array 310. The variable capacitors VC1 and VC2 may be connected in series between the nodes NO1 and NO2. For example, the node between the variable capacitors VC1 and VC2 may be configured to receive the first control signal Vctrl. The capacitor array 310 may be coupled between the nodes NO1 and NO2 and is controlled by the second control signal Cctrl (shown as Cctrl<N:0> in FIG. 3A). The voltage controlled oscillator VCO may also include an inductor L1, which may be coupled between the nodes NO1 and NO2.

As shown in FIG. 3B, the exemplary capacitor array 310 may include unit circuits UC0 to UCN. The second control signal Cctrl<N:0> may include N+1 bits, which are respectively sent to the unit circuits UC0 to UCN. For example, the unit circuit UC0 may include a transistor TA1 and capacitors CA1 and CA2. The capacitor CA1, the transistor TA1 and the capacitor CA2 are sequentially connected in series between the nodes NO1 and NO2. The control terminal of the transistor TA1 may receive a signal (e.g., the second control signal Cctrl<0>) corresponding to one bit of the second control signal Cctrl<N:0> via an inverter IV. When the transistor TA1 is turned on, capacitors CA1 and CA2 are enabled. When the transistor TA1 is turned off, capacitors CA1 and CA2 are disabled.

In this embodiment, the voltage controlled oscillator VCO may adjust the oscillation frequency of the generated oscillation signal OSC according to the control signals Vctrl and Cctrl. In detail, the capacitance values of the variable capacitors VC1 and/or VC2 of the voltage controlled oscillator VCO may be changed according to the voltage level of the first control signal Vctrl. The equivalent capacitance value of the capacitor array 310 of the voltage controlled oscillator VCO may also be adjusted according to the second control signal Cctrl. For example, The equivalent capacitance value of the capacitor array 310 may be increased or decreased by changing the number of enabled capacitors in the capacitor array 310. When the capacitance values of the variable capacitors VC1 and/or VC2 changes, or the equivalent capacitance value of the capacitor array 310 changes, the frequency of the generated oscillation signal OSC may be changed accordingly. Furthermore, in terms of the frequency-voltage response, the voltage controlled oscillator VCO may be operated within an optimal linear range. The frequency of the oscillation signal OSC changes substantially linearly with the level of the control voltage (e.g., the first control signal Vctrl). The optimal linear range may be indicated by, for example, the threshold voltages Vth1 and Vth2.

In the above embodiment, the voltage terminal VDD1 may be configured to receive an operating voltage, such as 3V or 9V, and the voltage terminal VS1 may be configured to receive a reference voltage, such as ground. It should be noted that the voltage controlled oscillator VCO shown in FIG. 3A is only used as an example and is not intended to limit the disclosure. For example, in other embodiments, the third and fourth transistors TO3, TO4 may be omitted from the voltage controlled oscillator VCO. In such a case, the resistor RO1 may be coupled between the voltage terminal VDD1 and the first transistor TO1, and coupled between the voltage terminal VDD1 and the second transistor TO2.

In some embodiments, due to, for example, variations in operating time or operating environment, the operating voltage, current, and temperature of the voltage controlled oscillator VCO may change, and thus the optimal linear range of may shift. In such a case, the voltage level of the DC component of the oscillation signal OSC (also referred to as the DC level) may change or shift (for example, increased or decreased). For example, a reference voltage generator may be provided in the frequency calibration circuit to generate a reference voltage which may be used to track the DC level of the oscillation signal OSC. For example, the reference voltage generator may be implemented by replicating at least a part of the voltage controlled oscillator VCO.

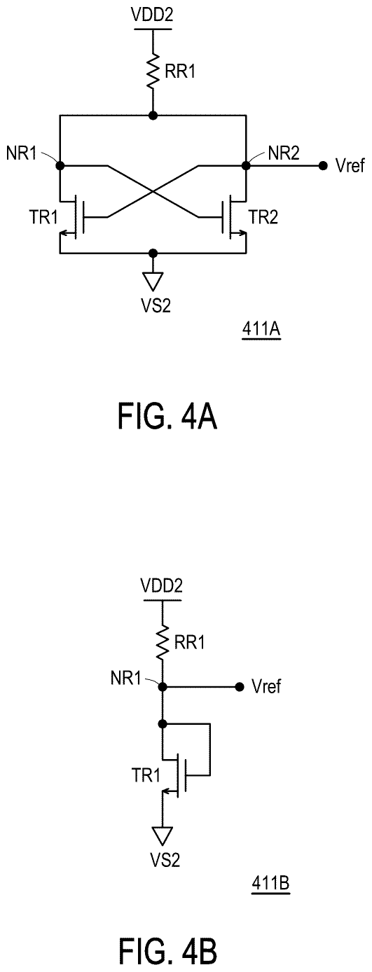

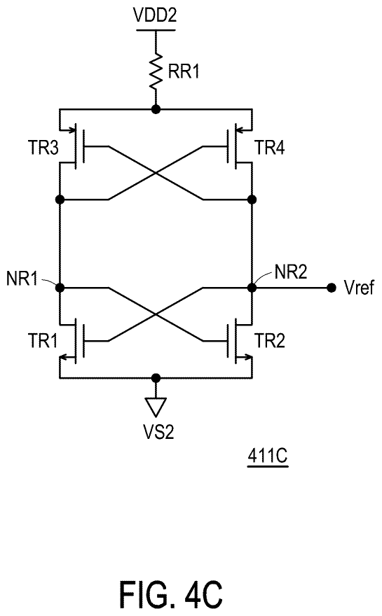

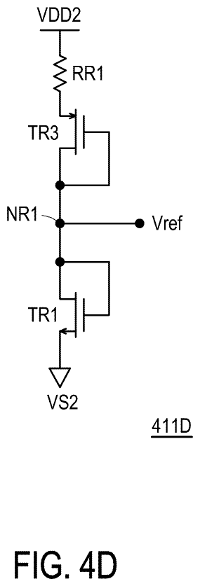

Referring to FIG. 4A to FIG. 4D, FIG. 4A to FIG. 4D are schematic diagrams of various reference voltage generators 411A to 411D according to at least one embodiment of the disclosure

As shown in FIG. 4A, the reference voltage generator 411A may include transistors TR1 to TR2 and a resistor RR1. For the sake of clarity, the transistors TR1 to TR2 of the reference voltage generator 411A herein may be referred to as the first to second transistors TR1 to TR2.

In detail, in the reference voltage generator 411A, as for the first transistor TR1, the first terminal of may be coupled to the voltage terminal VS2, the second terminal may be coupled to the first node NR1, and the control terminal may be coupled to the second node NR2. As for the second transistor TR2, the first terminal may be coupled to the voltage terminal VS2, the second terminal may be coupled to the second node NR2, and the control terminal may be coupled to the first node NR1. The resistor RR1 may be coupled between the voltage terminal VDD2 and the first node NR1 and also coupled between the voltage terminal VDD2 and the second node NR2. The first node NR1 or the second node NR2 may be configured to provide the reference voltage Vref.

In the embodiment shown in FIG. 4A, the transistors TR1, TR2 of the reference voltage generator 411A and the transistors TO1, TO2 of the voltage controlled oscillator VCO may be manufactured by using substantially the same process, so that they have substantially the same process voltage temperature (PVT) performance. Furthermore, the size of the first transistor TR1 of the reference voltage generator 411A relative to the size of the first transistor TO1 of the voltage controlled oscillator VCO may be a first ratio, the size of the second transistor TR2 of the reference voltage generator 411A relative to the size of the second transistor TO2 of the voltage controlled oscillator VCO may be a second ratio, and the first ratio may be substantially equal to the second ratio. For example, the first ratio and the second ratio may be, for example, approximately 1, in which case the level of the reference voltage Vref may be substantially equal to the DC level of the oscillation signal OSC.

As shown in FIG. 4B, the reference voltage generator 411B may include a first transistor TR1 and a resistor RR1. The first terminal of the first transistor TR1 may be coupled to the voltage terminal VS2. The control terminal and the second terminal of the first transistor TR1 may be coupled together and may be coupled to the first node NR1. The resistor RR1 may be coupled between the voltage terminal VDD2 and the first transistor TR1. The first node NR1 may be configured to provide the reference voltage Vref.

In the embodiment shown in FIG. 4B, the first transistor TR1 of the reference voltage generator 411B and the transistor TO1 or TO2 of the voltage controlled oscillator VCO may be manufactured by using substantially the same process. The first transistor TR1 of the reference voltage generator 411B may have the same electrical characteristics as the transistor TO1 or TO2 of the voltage controlled oscillator VCO, such as the same size, so that the level of the reference voltage Vref may be substantially equal to the DC level of the oscillation signal OSC. Alternatively, a certain ratio between the sizes of the first transistor TR1 of the reference voltage generator 411B and the transistor TO1 or TO2 of the voltage controlled oscillator VCO may be predetermined.

As shown in FIG. 4C, the reference voltage generator 411C may include first to fourth transistors TR1 to TR4 and a resistor RR1. The connection relationship between the first to second transistors TR1 to TR2 is similar to that shown in FIG. 4A and will not be repeated herein. As for the third transistor TR3, the first terminal may be coupled to the first node NR1, the second terminal may be coupled to the voltage terminal VDD2 via the resistor RR1, and the control terminal may be coupled to the second node NR2. As for the fourth transistor TR4, the first terminal may be coupled to the second node NR2, the second terminal may be coupled to the voltage terminal VDD2 via the resistor RR1, and the control terminal may be coupled to the first node NR1. The resistor RR1 may be coupled between the voltage terminal VDD2 and the third transistor TR3, and also coupled between the voltage terminal VDD2 and the fourth transistor TR4. In this embodiment, the transistors TR1 and TR2 may form a cross-coupled transistor pair, and the transistors TR1 and TR2 may be, for example, N-type transistors. The transistors TR3 and TR4 may form another cross-coupled transistor pair, and the transistors TR3 and TR4 may be, for example, P-type transistors.

In the embodiment shown in FIG. 4C, the first to fourth transistors TR1 to TR4 of the reference voltage generator 411C and the first to fourth transistors TO1 to TO4 of the voltage controlled oscillator VCO may be manufactured by using substantially the same process. Furthermore, the size of the first transistor TR1 of the reference voltage generator 411C relative to the size of the first transistor TO1 of the voltage controlled oscillator VCO may be a first ratio. The size of the second transistor TR2 of the reference voltage generator 411C relative to the size of the second transistor TO2 of the voltage controlled oscillator VCO may be a second ratio. The first ratio may be substantially equal to the second ratio. The size of the third transistor TR3 of the reference voltage generator 411C relative to the size of the third transistor TO3 of the voltage controlled oscillator VCO may be a third ratio. The size of the fourth transistor TR4 of the reference voltage generator 411C relative to the size of the fourth transistor TO4 of the voltage controlled oscillator VCO may be a fourth ratio. The third ratio may be substantially equal to the fourth ratio. For example, the first to fourth ratios may each be, for example, approximately 1, in which case the level of the reference voltage Vref may be substantially equal to the DC level of the oscillation signal OSC.

As shown in FIG. 4D, the reference voltage generator 411D may include transistors TR1, TR3 and a resistor RR1. The reference voltage generator 411D may be similar to the reference voltage generator 411B. The similarities will not be repeated herein, and only the exemplary differences will be described as follows. The reference voltage generator 411D may further include a third transistor TR3. The first terminal and the control terminal of the third transistor TR3 may be coupled together and further coupled to the first node NR1, and the second terminal may be coupled to the voltage terminal VDD2 via the resistor RR1.

In the embodiment shown in FIG. 4D, the first transistor TR1 of the reference voltage generator 411D and the transistor TO1 of the voltage controlled oscillator VCO may be manufactured by using substantially the same process. Further, the third transistor TR3 of the reference voltage generator 411D and the third transistor TO3 of the voltage controlled oscillator VCO may be manufactured by using substantially the same process. Furthermore, the size of the first transistor TR1 of the reference voltage generator 411D relative to the size of the first transistor TO1 of the voltage controlled oscillator VCO may be a first ratio. The size of the third transistor TR3 of the reference voltage generator 411D relative to the size of the third transistor TO3 of the voltage controlled oscillator VCO may be a third ratio. The first ratio may be substantially equal to the third ratio. For example, the first and third ratios may each be, for example, approximately 1, in which case the level of the reference voltage Vref may be substantially equal to the DC level of the oscillation signal OSC.

In the above embodiment, one of the reference voltage generators 411A to 411D may be implemented by replicating part of the voltage controlled oscillator VCO, so that the level of the reference voltage Vref provided by the reference voltage generator 411A to 411D may be related to the DC level of the oscillation signal OSC provided by the voltage controlled oscillator VCO. The DC level of the oscillation signal OSC may be substantially equal to the voltage level at the first node NO1 or the second node NO2. For example, the level of the reference voltage Vref may vary with the operating state (e.g., voltage, current, temperature and/or other related environmental factors) of the voltage controlled oscillator VCO. In some embodiments, the shift direction (or variation trend) of the level of the reference voltage Vref is the same as the shift direction of the DC level of the oscillation signal OSC. For example, when the DC level of the oscillation signal OSC increases, the level of the reference voltage Vref may increase.

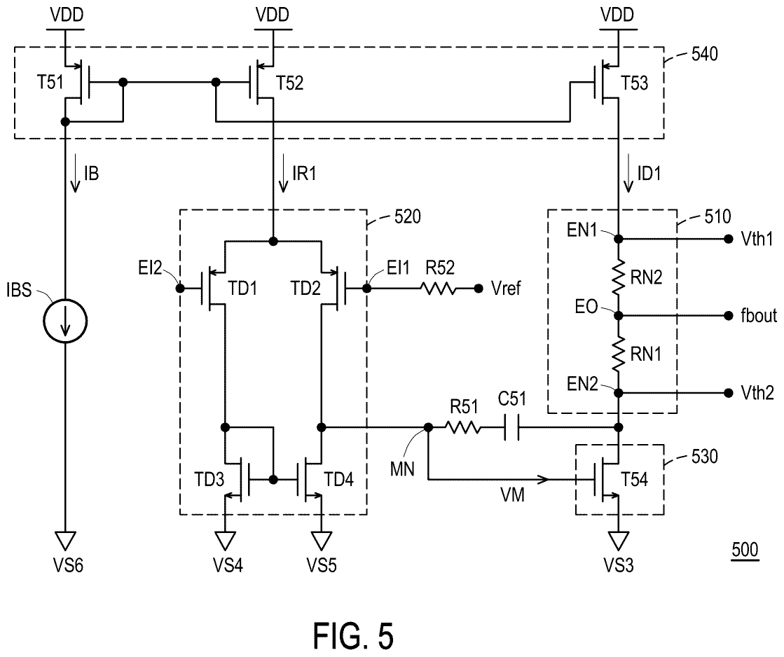

In some embodiments, the voltage buffer 212 may, for example, include an operational amplifier. As shown in FIG. 2, the voltage buffer 212 may include input terminals EI1 to EI2, an output terminal EO, and output nodes EN1 to EN2. The input terminals EI1 and EI2 may respectively be a non-inverting input terminal (i.e., the positive input terminal (+)) and an inverting input terminal (i.e., the negative input terminal (−)). The output terminal EO may be coupled to the input terminal EI2 to form a unit gain feedback circuit. The input terminal EI1 of the voltage buffer 212 may be coupled to the reference voltage generator 211 to receive the reference voltage Vref. The output nodes EN1 and EN2 may be respectively configured to output threshold voltages Vth1 and Vth2. For example, based on the unit gain feedback mechanism, the output terminal EO of the voltage buffer 212 may provide an output voltage fbout (as described below with reference to FIG. 5), which is substantially at the same level as the reference voltage Vref. Further, based on the generated output voltage fbout, the voltage buffer 212 may generate, for example, a high threshold voltage Vth1 and a low threshold voltage Vth2 respectively at the output nodes EN1 and EN2.

In some embodiments, the voltage levels of the threshold voltages Vth1 and Vth2 may be related to the level of the reference voltage Vref. As mentioned above, the shift direction of the level of the reference voltage Vref is the same as the shift direction of the DC level of the oscillation signal OSC. Therefore, the shift direction of the voltage levels of the threshold voltages Vth1 and Vth2 is the same as the shift direction of the DC level of the oscillation signal OSC. Therefore, the threshold voltages Vth1 and Vth2 may be dynamically adjusted according to the DC level of the oscillation signal OSC. Further details regarding the voltage buffer may be described below with reference to FIG. 5.

As shown in FIG. 2, the comparison logic circuit 213 may include at least one comparator CP1 to CP2 and a logic circuit 2131. The first input terminal (e.g., the negative input terminal) of the comparator CP1 may receive the first threshold voltage Vth1, and the second input terminal (e.g., the positive input terminal) may receive the first control signal Vctrl. The comparator CP1 may compare the levels of the first control signal Vctrl and the first threshold voltage Vth1 to generate a comparison signal CMP1. The first input terminal (e.g., the negative input terminal) of the comparator CP2 may receive the first control signal Vctrl, and the second input terminal (e.g., the positive input terminal) may receive the second threshold voltage Vth2. The comparator CP2 may compare the levels of the first control signal Vctrl and the second threshold voltage Vth2 to generate a comparison signal CMP2. It should be noted that in this embodiment, the number of comparators is only used as an example and is not intended to limit the disclosure. In other embodiments, the comparator CP1 or CP2 may be omitted.

Furthermore, the logic circuit 2131 is coupled to the output terminals of the comparators CP1 and CP2 to receive the comparison signals CMP1 and CMP2. The logic circuit 2131 performs logic operations based on the comparison signal CMP1 or CMP2 to generate the second control signal Cctrl. Specifically, the negative input terminal of the comparator CP1 may be coupled to the output node EN1 of the voltage buffer 212, and the positive input terminal may receive the first control signal Vctrl. The positive input terminal of the comparator CP2 may be coupled to the output node EN2 of the voltage buffer 212, and the negative input terminal may receive the first control signal Vctrl. For example, in the case where the threshold voltage Vth1 is higher than the threshold voltage Vth2, when the level of the first control signal Vctrl is higher than the threshold voltage Vth1, the level of the comparison signal CMP1 may be high (the logic value may be 1). In such a case, the level of the first control signal Vctrl is higher than the threshold voltage Vth2, and the level of the comparison signal CMP2 may be low (the logic value may be 0). When the level of the first control signal Vctrl is lower than the threshold voltage Vth1 and higher than the threshold voltage Vth2, the level of the comparison signal CMP1 may be low (the logic value may be 0), and the level of the comparison signal CMP2 may be low (the logical value may be 0). When the level of the first control signal Vctrl is lower than the threshold voltage Vth2, the level of the comparison signal CMP1 may be low (the logic value may be 0), and the level of the comparison signal CMP2 may be high (the logic value may be 1). The logic circuit 2131 may generate a digital second control signal Cctrl according to different combinations of comparison signals CMP1 and CMP2. As mentioned above, the second control signal Cctrl may be configured to enable or disable at least one unit circuit UC0 to UCN of the capacitor array 310 in the voltage controlled oscillator, thereby adjusting the frequency of the oscillation signal.

Referring to FIG. 5, FIG. 5 shows an exemplary voltage buffer 500. The voltage buffer 500 may include a differential amplification circuit 520, an output stage circuit 530, a voltage dividing circuit 510, a current generation circuit 540, and a bias current source IBS.

As shown in FIG. 5, the differential amplification circuit 520 may include transistors TD1 to TD4. For the sake of clarity, the transistors TD1 to TD4 of the differential amplification circuit 520 may be referred to as the first to fourth transistors TD1 to TD4. The transistors TD1 and TD2 may form a differential pair, and transistors TD3 and TD4 may form an active load. As for the first transistor TD1, the first terminal may be coupled to the second terminal of the third transistor TD3, the second terminal may be coupled to the current generation circuit 540, and the control terminal may be coupled to the input terminal EI2 of the voltage buffer 500. As for the second transistor TD2, the first terminal may be coupled to the second terminal of the fourth transistor TD4, the second terminal may be coupled to the current generation circuit 540, and the control terminal may be coupled to the input terminal EI1 of the voltage buffer 500. The input terminal EI1 of the voltage buffer 500 may further receive the reference voltage Vref via the resistor R52. As for the third transistor TD3, the first terminal may be coupled to the voltage terminal VS4, the second terminal and the control terminal may be coupled together and further coupled to the first terminal of the first transistor TD1. As for the fourth transistor TD4, the first terminal may be coupled to the voltage terminal VS5, the second terminal may be coupled to the first terminal of the second transistor TD2, and the control terminal may be coupled to the control terminal of the third transistor TD3. The second terminal of the fourth transistor TD4 may be further coupled to the intermediate node MN. In the above embodiment, the voltage buffer 500 may provide the intermediate signal VM at the intermediate node MN.

As shown in FIG. 5, the output stage circuit 530 may be coupled to the differential amplification circuit 520. In detail, the output stage circuit 530 includes a transistor T54. The first terminal of the transistor T54 may be coupled to the voltage terminal VS3, the second terminal may be coupled to the output node EN2, and the control terminal may be coupled to the intermediate node MN to receive the intermediate signal VM generated by the differential amplification circuit 520. In addition, the resistor R51 and the capacitor C51 may be connected in series between the output node EN2 and the intermediate node MN.

As shown in FIG. 5, the voltage dividing circuit 510 may be coupled to the output stage circuit 530 and coupled between the output node EN1 and the output node EN2. For example, the voltage dividing circuit 510 may include resistors RN1 and RN2 connected in series. One terminal of the resistor RN1 may be coupled to the output node EN2 and the other terminal may be coupled to the output terminal EO. One terminal of the resistor RN2 may be coupled to the output terminal EO, and the other terminal may be coupled to the output node EN1. As mentioned above, the output terminal EO may be coupled to the input terminal EI2.

As shown in FIG. 5, the current generation circuit 540 may be coupled to the differential amplification circuit 520, the output stage circuit 530, the voltage dividing circuit 510, and the bias current source IBS. The current generation circuit 540 may include transistors T51, T52, and T53. The transistors T51 and T52 may form a first current mirror, and the transistors T51 and T53 may form a second current mirror.

Specifically, the bias current source IBS may be coupled between the transistor T51 and the voltage terminal VS6 and be configured to provide bias current IB. The first current mirror of the current generation circuit 540 may be coupled to the bias current source IBS, so as to generate a first current IR1 by mirroring the bias current IB. The first current IR1 flows through the differential amplification circuit 520. Similarly, the second current mirror of the current generation circuit 540 may be coupled to the bias current source IBS, so as to generate a second current ID1 by mirroring the bias current IB. The second current ID1 flows through the voltage dividing circuit 510 and the output stage circuit 530.

The differential amplification circuit 520 may change the level of the intermediate signal VM according to the voltage difference between the input terminals EI1 and EI2. The output stage circuit 530 may change the level of the output voltage fbout at the output terminal EO according to the intermediate signal VM, so that the output voltage fbout is substantially equal to the reference voltage Vref. The voltage dividing circuit 510 may generate threshold voltages Vth1 and Vth2 respectively at the output nodes EN1 and EN2 based on the second current ID1 and the output voltage fbout.

In the above embodiment, the transistors T51 to T53, TD1, and TD2 may be P-type transistors, and the transistors TD3, TD4, and T54 may be N-type transistors. The voltage terminals VS1 to VS6 herein may be configured to receive a reference voltage, and they may be the same voltage terminal or different voltage terminals. Similarly, the voltage terminals VDD1 to VDD2 may be configured to an operating voltage, and they may be the same voltage terminal or different voltage terminals.

In at least one embodiment of the disclosure, during the operation of the signal generation device, the level of a threshold voltage may vary with the level of the reference voltage, and the level of the reference voltage may vary with the DC level of the oscillation signal from the voltage controlled oscillator. Therefore, when the optimal linear range of the voltage controlled oscillator shift with the operating state (e.g., voltage, current, temperature, and/or other relevant environmental factors), the threshold voltage(s) may change or shift accordingly. For example, a shift direction of the level of the threshold voltage may be the same as a shift direction of the level of the DC voltage of the oscillation signal. In other words, the threshold voltage may dynamically and adaptively indicate the optimal linear range of the voltage controlled oscillator, thereby achieving accurate frequency calibration, so that the oscillation frequency of the oscillation signal may meet the specification requirements.

Details of at least one embodiment are provided herein to assist in understanding the disclosure. However, it will be understood by those skilled in the art that the practice of the disclosure is not limited to these details. In some cases, detailed descriptions of some known elements, steps, procedures, circuits, materials, etc. may be omitted herein to avoid unnecessarily obscuring the disclosure. It should be noted that some embodiments may include additional elements/steps, may include equivalents of specific elements/steps, or may omit specific elements/steps. Furthermore, without departing from the spirit of the disclosure and without any conflict, features in different embodiments may be replaced, reorganized, mixed, and changed to achieve another embodiment, which still falls within the scope of the disclosure. In other words, features described in a drawing or an embodiment may not be limited to that drawing or that embodiment.

In the description herein and in each claim, the words “comprising”, “including”, “includes”, “having” and other words are open-ended words, so they should be interpreted to mean “including but not limited to . . . ”. Therefore, when these terms are used in the description of the disclosure, they may specify the presence of corresponding features but do not exclude the presence of other features. Herein, when it is mentioned that one element is coupled to another element, it may be directly coupled, or indirectly coupled via other elements. The reference voltage terminal described herein may provide a substantially stable reference voltage. The reference voltage terminal described herein may be, but is not limited to, the ground terminal. The reference voltage terminals described herein may be the same reference voltage terminal or different reference voltage terminals.

The above are only preferred embodiments of the disclosure, and all equivalent changes and modifications made in accordance with the claims of the disclosure shall fall within the scope of the disclosure.

What is claimed is:

1. A signal generation device, comprising:
a voltage controlled oscillator, providing an oscillation signal according to a first control signal and a second control signal; and
a frequency calibration circuit, coupled to the voltage controlled oscillator, the frequency calibration circuit is configured to compare the first control signal to at least one threshold voltage to generate at least one comparison signal, and is further configured to generate the second control signal according to the at least one comparison signal,
wherein a shift direction of a voltage level of the at least one threshold voltage is the same as a shift direction of a voltage level of a direct current (DC) component of the oscillation signal.

2. The signal generation device according to claim 1, wherein the frequency calibration circuit comprises:
a reference voltage generator, configured to provide a reference voltage, wherein the at least one threshold voltage is generated according to the reference voltage.

3. The signal generation device according to claim 2, wherein the voltage controlled oscillator comprises:
a first transistor, wherein as for the first transistor of the voltage controlled oscillator, a first terminal is coupled to a first voltage terminal, a second terminal is coupled to a first node of the voltage controlled oscillator, and a control terminal is coupled to a second node of the voltage controlled oscillator; and
a second transistor, wherein as for the second transistor of the voltage controlled oscillator, a first terminal is coupled to the first voltage terminal, a second terminal is coupled to the second node of the voltage controlled oscillator, and a control terminal is coupled to the first node of the voltage controlled oscillator.

4. The signal generation device according to claim 3, wherein the reference voltage generator comprises:
a first transistor, wherein as for the first transistor of the reference voltage generator, a first terminal is coupled to a second voltage terminal, a second terminal is coupled to a first node of the reference voltage generator, and a control terminal is coupled to a second node of the reference voltage generator; and
a second transistor, wherein as for the second transistor of the reference voltage generator, a first terminal is coupled to the second voltage terminal, a second terminal is coupled to the second node of the reference voltage generator, a control terminal is coupled to the first node of the reference voltage generator,
wherein the first node or the second node of the reference voltage generator is configured to output the reference voltage.

5. The signal generation device according to claim 4, wherein
a size of the first transistor of the reference voltage generator relative to a size of the first transistor of the voltage controlled oscillator is a first ratio,
a size of the second transistor of the reference voltage generator relative to a size of the second transistor of the voltage controlled oscillator is a second ratio, and
the first ratio is substantially equal to the second ratio.

6. The signal generation device according to claim 3, wherein the reference voltage generator comprises:
a first transistor, wherein as for the first transistor of the reference voltage generator, a first terminal is coupled to a second voltage terminal, a second terminal and a control terminal are coupled together and are coupled to a first node of the reference voltage generator,
wherein the first node of the reference voltage generator is configured to output the reference voltage.

7. The signal generation device according to claim 3, wherein the voltage controlled oscillator further comprises:
a third transistor, wherein as for the third transistor of the voltage controlled oscillator, a first terminal is coupled to the first node of the voltage controlled oscillator, a second terminal is coupled to a third voltage terminal, and a control terminal is coupled to the second node of the voltage controlled oscillator; and
a fourth transistor, wherein as for the fourth transistor of the voltage controlled oscillator, a first terminal is coupled to the second node of the voltage controlled oscillator, a second terminal is coupled to the third voltage terminal, and a control terminal is coupled to the first node of the voltage controlled oscillator.

8. The signal generation device according to claim 7, wherein the reference voltage generator comprises:
a first transistor, wherein as for the first transistor of the reference voltage generator, a first terminal is coupled to a second voltage terminal, a second terminal is coupled to a first node of the reference voltage generator, and a control terminal is coupled to a second node of the reference voltage generator;
a second transistor, wherein as for the second transistor of the reference voltage generator, a first terminal is coupled to the second voltage terminal, a second terminal is coupled to the second node of the reference voltage generator, and a control terminal is coupled to the first node of the reference voltage generator;
a third transistor, wherein as for the third transistor of the reference voltage generator, a first terminal is coupled to the first node of the reference voltage generator, a second terminal is coupled to a fourth voltage terminal, and a control terminal is coupled to the second node of the reference voltage generator; and
a fourth transistor, wherein as for the fourth transistor of the reference voltage generator, a first terminal is coupled to the second node of the reference voltage generator, a second terminal is coupled to the fourth voltage terminal, and a control terminal is coupled to the first node of the reference voltage generator,
wherein the first node or the second node of the reference voltage generator is configured to output the reference voltage.

9. The signal generation device according to claim 8, wherein
a size of the first transistor of the reference voltage generator relative to a size of the first transistor of the voltage controlled oscillator is a first ratio,
a size of the second transistor of the reference voltage generator relative to a size of the second transistor of the voltage controlled oscillator is a second ratio, and the first ratio is substantially equal to the second ratio, and wherein
a size of the third transistor of the reference voltage generator relative to a size of the third transistor of the voltage controlled oscillator is a third ratio,
a size of the fourth transistor of the reference voltage generator relative to a size of the fourth transistor of the voltage controlled oscillator is a fourth ratio, and the third ratio is substantially equal to the fourth ratio.

10. The signal generation device according to claim 7, wherein the reference voltage generator comprises:
a first transistor, wherein as for the first transistor of the reference voltage generator, a first terminal is coupled to a second voltage terminal, a second terminal and a control terminal are coupled together and are coupled to a first node of the reference voltage generator; and
a third transistor, wherein as for the third transistor of the reference voltage generator, a first terminal and a control terminal are coupled together and are coupled to the first node of the reference voltage generator, and a second terminal is coupled to a fourth voltage terminal,
wherein the first node of the reference voltage generator is configured to output the reference voltage.

11. The signal generation device according to claim 10, wherein
a size of the first transistor of the reference voltage generator relative to a size of the first transistor of the voltage controlled oscillator is a first ratio,
a size of the third transistor of the reference voltage generator relative to a size of the third transistor of the voltage controlled oscillator is a third ratio, and
the first ratio is substantially equal to the third ratio.

12. The signal generation device according to claim 3, wherein a level of the reference voltage of the reference voltage generator is related to a voltage level at the first node or the second node of the voltage controlled oscillator.

13. The signal generation device according to claim 4, wherein
the voltage controlled oscillator further comprises a resistor, coupled between a third voltage terminal and the first transistor of the voltage controlled oscillator, and coupled between the third voltage terminal and the second transistor of the voltage controlled oscillator; and
the reference voltage generator further comprises a resistor, coupled between a fourth voltage terminal and the first transistor of the reference voltage generator.

14. The signal generation device according to claim 8, wherein
the voltage controlled oscillator further comprises a resistor, coupled between a third voltage terminal and the third transistor of the voltage controlled oscillator, and coupled between the third voltage terminal and the fourth transistor of the voltage controlled oscillator;
the reference voltage generator further comprises a resistor, coupled between a fourth voltage terminal and the third transistor of the reference voltage generator.

15. The signal generation device according to claim 2, wherein the frequency calibration circuit further comprises:
a voltage buffer, coupled to the reference voltage generator, wherein the voltage buffer is configured to receive the reference voltage and to generate the at least one threshold voltage according to the reference voltage, wherein the at least one threshold voltage comprises a first threshold voltage and a second threshold voltage.

16. The signal generation device according to claim 15, wherein the voltage buffer comprises:
a first input terminal, coupled to the reference voltage generator and configured to receive the reference voltage;
a second input terminal;
an output terminal, coupled to the second input terminal and configured to provide an output voltage;
a first output node, configured to output the first threshold voltage; and
a second output node, configured to output the second threshold voltage.

17. The signal generation device according to claim 16, wherein the voltage buffer further comprises:
a differential amplification circuit, coupled to the first input terminal and the second input terminal and configured to provide an intermediate signal at an intermediate node, wherein the differential amplification circuit is configured to change a level of the intermediate signal according to a voltage difference between the first input terminal and the second input terminal;
an output stage circuit, coupled to the intermediate node and to the output terminal, wherein the output stage circuit is configured to receive the intermediate signal and to change a level of the output voltage according to the intermediate signal;
a voltage dividing circuit, coupled to the first output node and the second output node, the voltage dividing circuit is configured to generate the first threshold voltage and the second threshold voltage based on a second current and the output voltage; and
a current generation circuit, coupled to the differential amplification circuit, the output stage circuit, and the voltage dividing circuit, wherein the current generation circuit is configured to receive a bias current and to generate a first current and the second current according to the bias current, wherein the first current flows through the differential amplification circuit, and the second current flows through the voltage dividing circuit and the output stage circuit.

18. The signal generation device according to claim 17, wherein
the differential amplification circuit comprises:
a first transistor, wherein as for the first transistor of the differential amplification circuit, a control terminal is coupled to the second input terminal, and a second terminal is coupled to the current generation circuit; and
a second transistor, wherein as for the second transistor of the differential amplification circuit, a control terminal is coupled to the first input terminal and is configured to receive the reference voltage via a resistor, and a second terminal is coupled to the current generation circuit; and wherein
the output stage circuit comprises:
a transistor, wherein as for the transistor of the output stage circuit, a first terminal is coupled to a fifth voltage terminal, a second terminal is coupled to the second output node, and a control terminal is coupled to the intermediate node; and wherein
the voltage dividing circuit comprises:
a first resistor; and
a second resistor, coupled in series with the first resistor between the first output node and the second output node; and wherein
the current generation circuit comprises:
a first current mirror and a second current mirror, wherein the first current mirror is configured to provide the first current according to the bias current, and the second current mirror is configured to provide the second current according to the bias current.

19. The signal generation device according to claim 18, wherein the differential amplification circuit further comprises:
a third transistor, wherein as for the third transistor of the differential amplification circuit, a first terminal is coupled to a sixth voltage terminal, a second terminal and a control terminal are coupled together and are coupled to a first terminal of the first transistor of the differential amplification circuit; and
a fourth transistor, wherein as for the fourth transistor of the differential amplification circuit, a first terminal is coupled to a seventh voltage terminal, a second terminal is coupled to the intermediate node, and a control terminal is coupled to the control terminal of the third transistor of the differential amplification circuit.

20. The signal generation device according to claim 15, wherein the frequency calibration circuit further comprises a comparison logic circuit coupled to the voltage buffer, wherein the comparison logic circuit comprises:
a first comparator, configured to compare the first control signal to the first threshold voltage to generate a first comparison signal;
a second comparator, configured to compare the first control signal to the second threshold voltage to generate a second comparison signal; and
a logic circuit, coupled to the first comparator and the second comparator and configured to receive the first comparison signal or the second comparison signal, wherein the logic circuit is configured to perform logic operation according to the first comparison signal or the second comparison signal and thus configured to generate the second control signal.

21. A frequency calibration circuit, coupled to a voltage controlled oscillator configured to provide an oscillation signal according to a first control signal and a second control signal, wherein
the frequency calibration circuit is configured to compare the first control signal to at least one threshold voltage to generate at least one comparison signal, and is further configured to generate the second control signal according to the at least one comparison signal, wherein a shift direction of a voltage level of the at least one threshold voltage is the same as a shift direction of a voltage level of a direct current (DC) component of the oscillation signal.
